(19) United States
(12) Patent Application Publication
(10) Pub. No.: US 2023/0013442 A1
(43) Pub. Date: Jan. 19, 2023

(54) THERMAL MODULE

(71) Applicant: ASIA VITAL COMPONENTS CO., LTD., New Taipei City (TW)

(72) Inventor: Wen-Ji Lan, New Taipei City (TW)

(21) Appl. No.: 17/377,386

(22) Filed: Jul. 16, 2021

(51) Int. Cl. H05K 7/20

(52) U.S. Cl. CPC H05K 7/20336

(57) ABSTRACT

A thermal module includes a base seat and multiple heat pipes. The base seat has a heat absorption side and a heat conduction side. Each heat pipe has a heat absorption end and a heat dissipation end. The heat absorption end has a pair of long sides and a pair of short sides. The long sides and the short sides are connected with each other in the form of a loop to form the heat absorption end. The heat pipes are assembled with each other with the long sides attached to each other. The heat pipes are assembled with the base seat with the short sides attached to the heat conduction side of the base seat. By means of the above arrangement, the number of the heat pipes disposed in a limited area or space can be greatly increased to enhance the heat conduction efficiency.

### BACKGROUND OF THE INVENTION

### 1. Field of the Invention

The present invention relates generally to a thermal module, and more particularly to a thermal module, which has enhanced heat dissipation efficiency.

### 2. Description of the Related Art

The current electronic device has at least one heat source inside. When calculating data, the heat source will generate heat in the electronic device. The heat source is often positioned near the center of the electronic device. It is hard to conduct the heat generated by the heat source to outer side. Therefore, some manufacturers arrange heat conduction and heat dissipation components on the heat source for dissipating the heat. The most often seen heat conduction components are heat pipes, vapor chambers, etc. The most often used heat dissipation components are heat sink, radiating fin assembly, etc. The heat conduction component is in contact with the heat source to absorb the heat generated by the heat source. Then the heat conduction component conducts the heat to the heat dissipation component such as the heat sink to dissipate the heat.

Please refer to FIGS. 5 and 6. FIG. 5 is a perspective view of a conventional thermal module. FIG. 6 is a perspective view of another conventional thermal module. In the conventional thermal module, the heat pipes 8 for absorbing heat must be first connected with the base seat 9 so as to be secured to a heat source. For example, the space or area of a common base seat 9 has a distance or width of about 30∼60 mm for mounting the heat pipes 8. In the case that a heat pipe with a diameter of 10 mm is selectively used, at most only 3∼5 heat pipes can be disposed on the base seat. Moreover, the heat pipes are in connection and contact with the base seat simply by one point or a line. In order to increase the contact area between the heat pipe 8 and the base seat 9, some manufacturers flatten the heat pipes 8 into a flat form. One side of the flat heat pipe is attached to a surface of the base seat 9 so as to increase the contact area between the heat pipe and the base seat. This can increase the contact area between the heat pipe and the base seat. However, the distance or width of the base seat for arrangement of the heat pipes is fixed and limited. As a result, the number of the flat heat pipes 8 disposed on the base seat is even less than the number of the circular heat pipes prior to flattening. Therefore, the number of the heat pipes is insufficient so that the heat dissipation efficiency achieved by the thermal module may be poorer.

It is therefore tried by the applicant to provide a thermal module, which can enhance the heat conduction efficiency in a limited space as well as keep good heat contact area to avoid thermal resistance phenomenon.

### SUMMARY OF THE INVENTION

It is therefore a primary object of the present invention to provide a thermal module, which can enhance the heat conduction efficiency.

To achieve the above and other objects, the thermal module of the present invention includes a base seat and multiple heat pipes.

The base seat has a heat absorption side and a heat conduction side. Each heat pipe has a heat absorption end and a heat dissipation end. The heat absorption end is formed of a pair of long sides and a pair of short sides. The long sides and the short sides are connected with each other in the form of a loop to form the heat absorption end. The heat pipe has a first chamber inside the heat pipe. A first capillary structure is disposed on a wall face of the first chamber. A working fluid is filled in the first chamber. The heat pipes are assembled with each other with the long sides attached to each other. The heat pipes are assembled with the base seat with the short sides attached to the heat conduction side of the base seat. By means of the above arrangement, the number of the heat pipes disposed on the base seat is increased to enhance the heat conduction efficiency.

By means of the thermal module of the present invention, more heat pipes can be disposed in a limited unit distance, length (width) or volume. By means of the more heat pipes, the heat conduction efficiency of the entire thermal module is enhanced to avoid accumulation of heat in the heat source.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective view of a first embodiment of the thermal module of the present invention;

FIG. 2 is a sectional assembled view of the first embodiment of the thermal module of the present invention;

FIG. 3 is a sectional assembled view of a second embodiment of the thermal module of the present invention;

FIG. 4 is a perspective exploded view of a third embodiment of the thermal module of the present invention;

FIG. 5 is a perspective view of a conventional thermal module; and

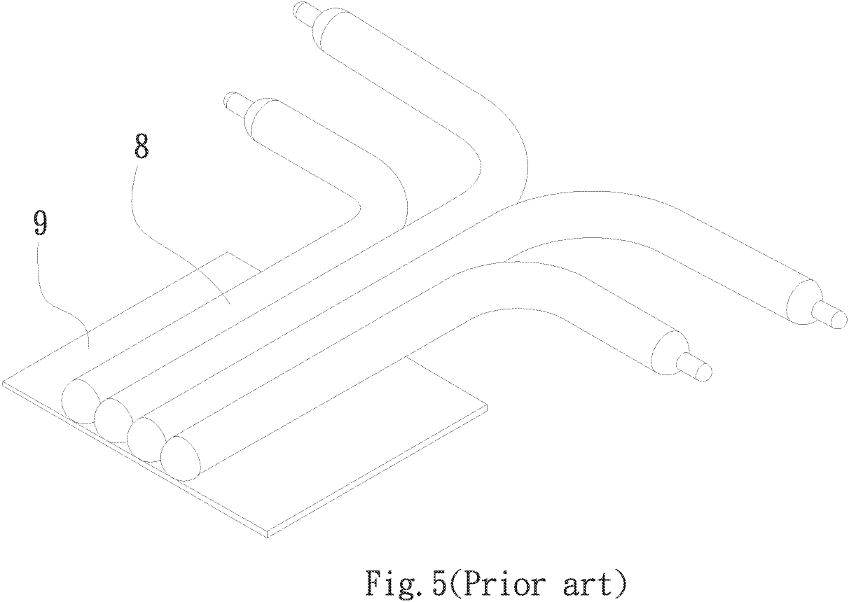

FIG. 6 is a perspective view of another conventional thermal module.

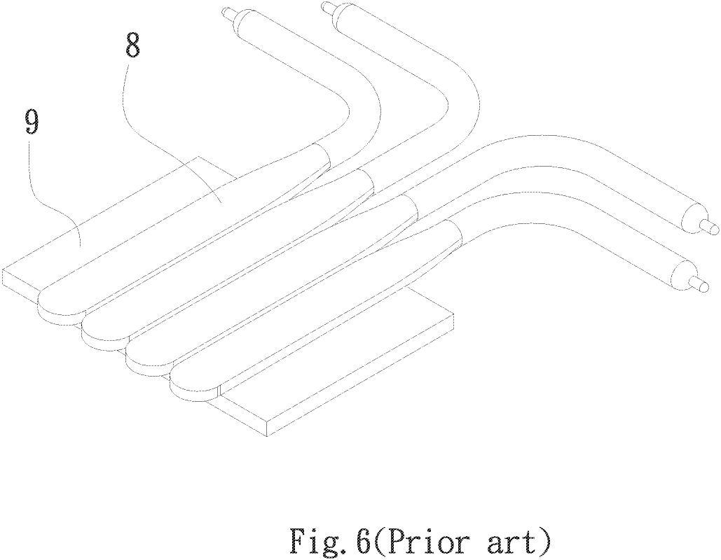

### DETAILED DESCRIPTION OF THE PREFERRED EMBODIMENTS

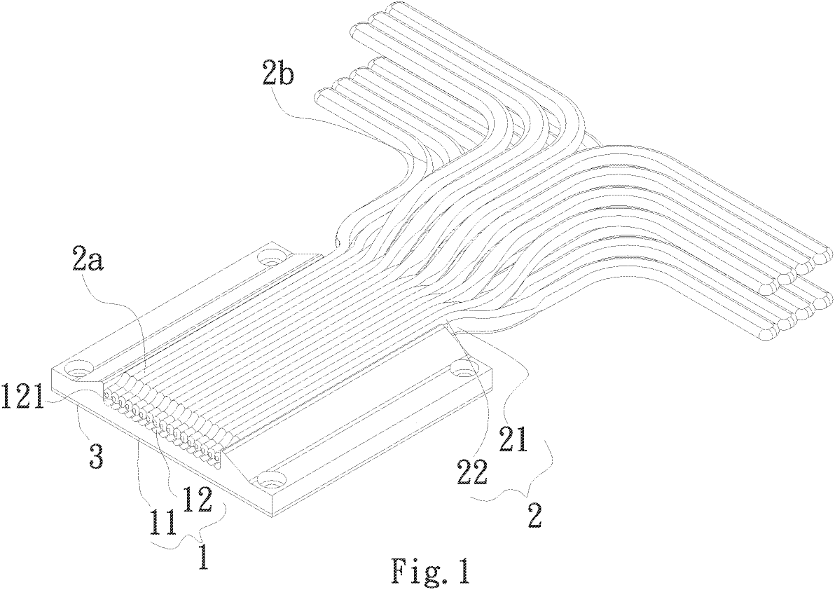

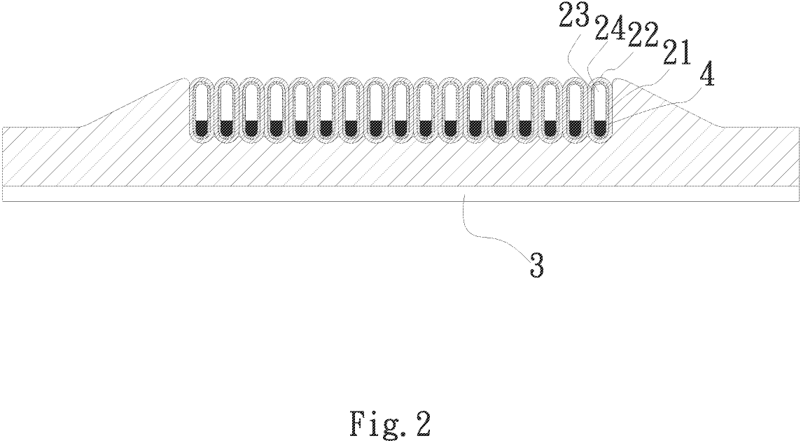

Please refer to FIGS. 1 and 2. FIG. 1 is a perspective view of a first embodiment of the thermal module of the present invention. FIG. 2 is a sectional assembled view of the first embodiment of the thermal module of the present invention. As shown in the drawings, the thermal module of the present invention includes a base seat 1 and multiple heat pipes 2.

The base seat 1 has a heat absorption side 11 and a heat conduction side 12. The heat absorption side 11 and the heat conduction side 12 are respectively positioned on upper and lower sides of the base seat 1. The heat absorption side 11 is in contact with at least one corresponding heat source 3 to absorb the heat generated by the heat source 3. The heat conduction side 12 is connected with heat conduction components or heat dissipation components to conduct the heat. In this embodiment, the heat conduction side 12 is, but not limited to, connected with heat conduction components to conduct the heat for illustration. The heat conduction components are heat pipes 2 for illustration.

Each heat pipe 2 has a heat absorption end 2a and a heat dissipation end 2b. The heat absorption end 2a has a pair of long sides 21 and a pair of short sides 22. The long sides 21 and the short sides 22 extend along a periphery of the heat pipe 2 and are connected with each other in the form of a loop to form the heat absorption end 2a. The heat pipe 2 has a first chamber 24 inside the heat pipe 2. At least one first capillary structure 23 is disposed on a wall face of the first chamber 24. A working fluid 4 is filled in the first chamber 24. The long sides 21 of the heat pipe 2 are plane faces, while the short sides 22 are selectively arc faces or plane faces. The heat pipes 2 are assembled with each other with the long sides 21 attached to each other, whereby the heat can be quickly transferred between the heat pipes 2. The heat pipes 2 are assembled with the base seat 1 with the short sides 22 attached to the heat conduction side 12 of the base seat 1.

The first capillary structure 23 is selected from a group consisting of sintered powders, channels, mesh body and any combination thereof. The heat pipes 2 and the base seat 1 are made of a material selected from a group consisting of copper, aluminum, stainless steel, titanium, titanium alloy and aluminum alloy. The heat pipes 2 and the base seat 1 can be made of the same material or different materials. The working fluid 4 is selected from a group consisting of coolant, acetone, pure water and alcohol.

The heat conduction side 12 of the base seat 1 has multiple channels 121. The short sides 22 of the heat pipes 2 have a configuration identical to that of the channels 121. The heat pipes 2 are connected with the base seat 1 with the short sides 22 received in the channels 121.

The part of the heat pipe 2 in contact with the heat conduction side 12 of the base seat 1 is not limited to the head end or tail end of the heat pipe 2. Alternatively, the part of the heat pipe 2 in contact with the heat conduction side 12 of the base seat 1 can be a middle section of the heat pipe 2. In this embodiment, the of the heat pipe 2 in contact with the heat conduction side 12 of the base seat 1 is, but not limited to, the head end or tail end of the heat pipe 2 for illustration. By means of the above arrangement, the number of the heat pipes 2 disposed on the base seat 1 can be increased to enhance the heat conduction efficiency. The heat absorption end 2a of the heat pipe 2 has a cross-sectional configuration identical to or different from the configuration of the other parts of the heat pipe 2.

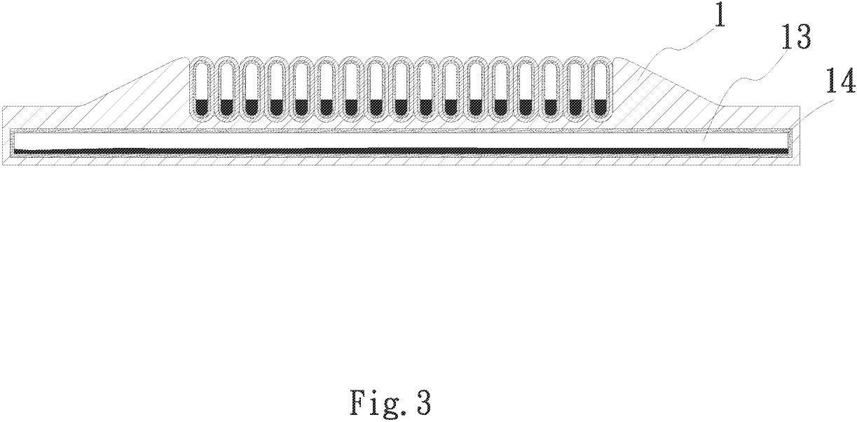

Please refer to FIG. 3, which is a sectional assembled view of a second embodiment of the thermal module of the present invention. The second embodiment is partially identical to the first embodiment in structure and thus will not be redundantly described hereinafter. The second embodiment is different from the first embodiment in that the base seat 1 has a second chamber 13 inside the base seat 1. At least one second capillary structure 14 is disposed in the second chamber 13. The second capillary structure 14 is selected from a group consisting of sintered powders, channels, mesh body and any combination thereof

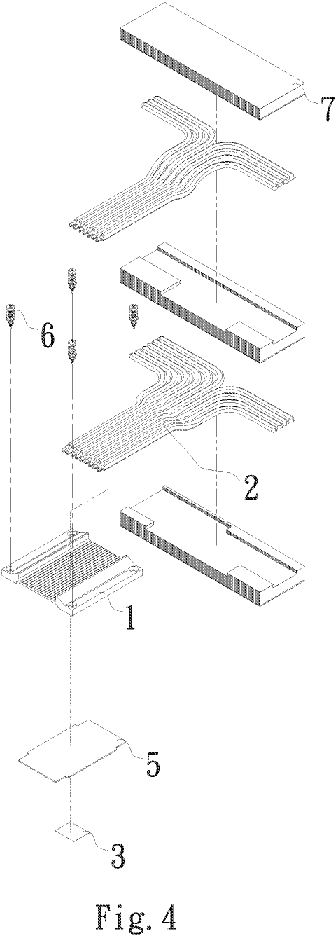

Please refer to FIG. 4, which is a sectional assembled view of a third embodiment of the thermal module of the present invention. The third embodiment is partially identical to the first embodiment in structure and thus will not be redundantly described hereinafter. The third embodiment is different from the first embodiment in that the heat absorption side 11 of the base seat 1 is attached to one side of a vapor chamber 5. The other side of the vapor chamber 5 is in contact with a heat source 3 to absorb the heat generated by the heat source 3. In this embodiment, the base seat 1 mainly serves as a carrier body for securing the heat pipes 2 and the vapor chamber 5 so as to form a thermal module. It is another effect of the base seat 1 to securely connect the entire thermal module (the base seat 1, the heat pipes 2 and the vapor chamber 5) with the heat source 3. The base seat 1 can be locked with the heat source 3 by means of screw members 6. Alternatively, a latch device (not shown) is used to hold or retain the base seat 1 so as to secure the base seat 1 to a surrounding (not shown) of the heat source 3.

In the above first, second and third embodiments, one end, (that is, the heat dissipation end) of the heat pipe 1 can be connected with at least one heat sink 7 or radiating fin assembly or water-cooling module to cool the heat dissipation end. When the heat absorption end 2a of the heat pipe 1 absorbs the heat generated by the heat source 3, the heat pipe 1 axially conducts the heat to a remote end. Then the heat sink or radiating fin assembly or water-cooling module performs heat-change with the ambient air.

In the present invention, the heat pipes are assembled with each other with the long sides attached to each other. The heat pipes are assembled with the base seat with the short sides attached to the heat conduction side of the base seat. By means of such design, the number of the heat pipes disposed in a limited area or space can be greatly increased to enhance the heat conduction efficiency and promote the heat dissipation performance of the entire thermal module. Therefore, the present invention can improve the shortcoming of the conventional thermal module that the distance or width of the base seat for arrangement of the heat pipes is fixed and limited so that the number of the heat pipes disposed on the base seat is insufficient and the heat conduction efficiency is poor.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A thermal module comprising:
a base seat having a heat absorption side and a heat conduction side; and
multiple heat pipes, each heat pipe having a heat absorption end and a heat dissipation end, the heat absorption end having a pair of long sides and a pair of short sides, the long sides and the short sides extending along a periphery of the heat pipe and being connected with each other in the form of a loop to form the heat absorption end, the heat pipe having a first chamber inside the heat pipe, at least one first capillary structure being disposed on a wall face of the first chamber, a working fluid being filled in the first chamber, the heat pipes being assembled with each other with the long sides attached to each other, the heat pipes being assembled with the base seat with the short sides attached to the heat conduction side of the base seat.

2. The thermal module as claimed in claim 1, wherein the heat conduction side of the base seat has multiple channels, the short sides of the heat pipes having a configuration identical to that of the channels, the heat pipes being connected with the base seat with the short sides received in the channels.

3. The thermal module as claimed in claim 1, wherein the first capillary structure is selected from a group consisting of sintered powders, channels and mesh body.

4. The thermal module as claimed in claim 1, wherein the heat pipes and the base seat are made of a material selected from a group consisting of copper, aluminum, stainless steel, titanium, titanium alloy and aluminum alloy and the heat pipes and the base seat are made of the same material or different materials.

5. The thermal module as claimed in claim 1, wherein the working fluid is selected from a group consisting of coolant, acetone, pure water and alcohol.

6. The thermal module as claimed in claim 1, wherein the base seat has a second chamber inside the base seat, at least one second capillary structure being disposed in the second chamber.

7. The thermal module as claimed in claim 1, wherein the heat absorption end of the heat pipe has a cross-sectional configuration identical to or different from the configuration of the other parts of the heat pipe.

8. The thermal module as claimed in claim 1, wherein the heat absorption side of the base seat is attached to one side of a vapor chamber, the other side of the vapor chamber being in contact with a heat source.

9. The thermal module as claimed in claim 1, wherein the heat dissipation end of the heat pipe is connected with at least one heat sink or radiating fin assembly or water-cooling module to cool the heat dissipation end.
